(19) United States
(12) Patent Application Publication
(10) Pub. No.: US 2012/0229149 A1
(43) Pub. Date: Sep. 13, 2012

(54) METHOD FOR DETERMINING LOAD CAPACITANCE OF AN OSCILLATOR CIRCUIT, OSCILLATOR CIRCUIT AND ELECTRONIC APPARATUS

(76) Inventor: Hiroyuki Souma, Chiba-shi (JP)

(21) Appl. No.: 13/403,270

(22) Filed: Feb. 23, 2012

(30) Foreign Application Priority Data
Mar. 9, 2011 (JP) 2011-052137

(51) Int. Cl. G01R 27/26

(52) U.S. Cl. 324/658

(57) ABSTRACT

It is an object of the present invention to provide a method for determining the load capacitance CL of an oscillator circuit having a low load capacitance. To attain the object, we provide a method for determining the load capacitance CL of an oscillator circuit, wherein, when a drive current and a load capacitance of the oscillator circuit with a negative resistance RL1 are Ios1 and CL1, respectively, a load capacitance CL2 for changing the drive current of the oscillator circuit to Ios2 (<Ios1) is given by: CL2=CL1*(Ios2/Ios1)^{1/2}.

### RELATED APPLICATIONS

This application claims priority under 35 U.S.C. §119 to Japanese Patent Application No. 2011-052137 filed on Mar. 9, 2011, the entire content of which is hereby incorporated by reference.

### BACKGROUND OF THE INVENTION

1. Field of the Invention

The present invention relates to a method for providing a crystal oscillator circuit with low power consumption, and particularly relates to a method for determining the load capacitance of a crystal oscillator circuit and a method for determining the negative resistance RL of a crystal oscillator circuit. Also, the invention relates to an oscillator circuit and an electronic apparatus designed using these methods.

2. Description of the Related Art

For a portable apparatus, such as a watch or mobile phone, long time operation without charging and reduction in frequency of charging a built-in battery are desired. Accordingly, there is a growing demand for reducing drive power of an oscillator circuit including a piezoelectric device, such as a crystal resonator, used for the portable apparatus and significantly reducing power consumption of the oscillator circuit in standby mode (i.e., when the oscillator circuit is oscillating in unloaded condition).

FIG. 3 shows a typical oscillator circuit including a crystal resonator, including: a CMOS inverter IV01 as an inverting amplifier; a crystal resonator X2 connected between the input terminal XCIN and output terminal XCOUT of the CMOS inverter IV01; a capacitor providing a load capacitance Cg connected between the input terminal XCIN of the CMOS inverter IV01 and the power supply terminal Vss of a ground potential; and a capacitor providing a load capacitance Cd connected between the output terminal XCOUT of the CMOS inverter IV01 and the power supply terminal Vss of the ground potential.

The CMOS inverter IV01 includes a CMOS inverter consisting of a PMOS transistor PM11 and an NMOS transistor NM11 connected in series between a first power supply terminal and a second power supply terminal supplied with a power supply voltage Vdd and the ground potential, respectively, and a feedback resistor Rf. Drive current adjusting resistors r1 and r2 limit drive current for exciting the crystal resonator X2, the resistor r1 being connected between the source of the PMOS transistor PM11 of the CMOS inverter IV01 and the first power supply terminal, the resistor r2 being connected between the NMOS transistor NM11 of the CMOS inverter IV01 and the second power supply terminal.

In recent years, there is a demand for reducing power consumption of an oscillator circuit included in a portable apparatus or the like. In order to meet this demand, drive current of a crystal resonator of the oscillator circuit needs to be reduced. In order to do this, reducing the transconductance Gm of a CMOS inverter of the oscillator circuit may be appropriate. But, reducing the transconductance Gm may reduce the oscillation margin of the oscillator circuit.

The oscillation margin M of the oscillator circuit is given by Eq. (1) as follows:

M={|−Gm|/(ω²Cg·Cd)}*(1/R1(max))=|RL|/R1(max) Eq. (1)

where ω is angular frequency of oscillation frequency, RL is negative resistance, R1(max) is the maximum value of the effective resistance R1 of the crystal resonator, and the oscillation margin M needs to be 5 or more.

Since the effective resistance R1 of the crystal resonator is to be determined in order to downsize the crystal resonator, the effective resistance R1 cannot be reduced too much. So, in order to maintain the oscillation margin M of the oscillator circuit while reducing the transconductance Gm, the load capacitances Cg and/or Cd of the capacitors providing the external load capacitance of the CMOS inverter should be reduced. So, in order to achieve this, the crystal resonator of the oscillator circuit needs to have a load capacitance CL meeting the requirement of reducing power consumption of a built-in IC, such as a microcomputer. In view of this, the applicant has already proposed the reduction of the load capacitance CL, or lower CL (3-5 pF) with respect to the load capacitance CL of 12.5 pF for a conventional crystal resonator (JP-A-2008-205658).

However, reducing the load capacitance CL makes noticeable a problem of the capacitance tolerance of load capacitance CL and the frequency γdeviation Δf of oscillation frequency. For example, the oscillation frequency stability Δf (in ppm) when the load capacitance CL varies by ΔC (±5%) which is within a normal capacitance tolerance is 7.3 ppm with a load capacitance CL of 12.5 pF and ΔC of 1.25 pF; 13.2 ppm with a load capacitance CL of 6 pF and ΔC of 0.6 pF; and 20.5 ppm with a load capacitance CL of 3 pF and ΔC of 0.3 pF.

This means that the load capacitance CL of 3 pF exhibits 2.8 times as much frequency deviation as the conventional load capacitance CL of 12.5 pF. So, in order to reduce the load capacitance CL (achieve reduced CL), the oscillation frequency stability with respect to the capacitance tolerance of the load capacitance CL needs to be improved.

FIG. 4 shows an equivalent circuit of the circuit in FIG. 3 between the input/output terminals XCIN and XCOUT on the crystal resonator side. The crystal resonator X2 and the load capacitance CL are connected in series. The crystal resonator is expressed as a circuit in which a serial resonance circuit of an inductance L1, a capacitance C1 and a resistance R1 that equivalently represents a mechanical resonance due to a piezoelectric effect and an inter-electrode capacitance C0 are connected in parallel. Also, various stray capacitances due to a CMOS semiconductor substrate, signal wires and the like exist between the input/output terminals XCIN and XCOUT. Denoting a combined stray capacitance of these stray capacitances by Cs, the load capacitance CL is a parallel connection of the stray capacitance Cs and the external capacitances Cg and Cd connected in series as shown in FIG. 5.

Accordingly,

CL=Cs+Cg*Cd/(Cg+Cd) Eq. (2).

Selecting external capacitors Cg and Cd matching with the oscillation frequency so that the load capacitance CL will be 2-6 pF that meets the relation of Eq. (2) can improve the oscillation frequency stability. Specifically, since the load capacitance CL is the sum of the stray capacitance Cs and the external capacitance Cext {=Cg*Cd/(Cg+Cd)}, selecting the value of the external capacitance Cext to be corresponding to the difference between the load capacitance CL and the stray capacitance Cs may satisfy Eq. (2), meaning that the load capacitance CL of the crystal resonator may match with the load capacitance on the oscillator circuit side with respect to the crystal resonator.

FIG. 6 shows a relation between the drive current and load capacitance CL of the crystal oscillator circuit with a crystal resonator frequency of 32.768 kHz. This is a result of measuring the drive current Ios (nA) with respect to variable load capacitance CL (pF) with the negative resistance RL fixed to 1000 kΩ. As seen from FIG. 6, the drive current significantly decreases as the load capacitance CL decreases. For example, with a conventionally employed load capacitance of 12.5 pF, the drive current is about 1.5 μA, whereas, with a load capacitance of 2.2 pF, the drive current is 0.055 μA, reduced to about 4%. Thus, reducing the load capacitance CL contributes to reduced power consumption of the crystal oscillator circuit, and furthermore contributes to reduced power consumption of an electronic apparatus including the crystal oscillator circuit.

Reducing the load capacitance CL allows the drive current of the crystal oscillator circuit to be reduced. So, in order to obtain several desired drive currents Ios, various load capacitances CL need to be prepared with respect to one negative resistance RL. With respect to a different negative resistances RL, different load capacitances CL need to be prepared to obtain a predetermined drive current Ios. Such a method requires many load capacitances CL to be prepared, which increases the number of parts. Furthermore, as for the negative resistance RL, the lower limit of the negative resistance RL can be determined by setting the oscillation margin M to an appropriate value greater than 5 using the above-described Eq. (1), but the upper limit of the negative resistance RL is unknown, so the negative resistance RL may be set excessively high. Excessively high negative resistance RL makes the effect of the feedback resistance Rf nonnegligible and may cause abnormal (unstable) oscillation.

### SUMMARY OF THE INVENTION

It is an object of the present invention to provide a method for obtaining a predetermined drive current depending on various negative resistance with several prepared load capacitances CL in a (reduced CL) crystal oscillator circuit having a low load capacitance of less than about 10 pF, preferably less than about 8 pF and more preferably less than about 6 pF, and further provide a method for determining the range of the negative resistance in order to facilitate designing a crystal oscillator circuit and an IC including the crystal oscillator circuit.

Specifically, the invention is as described in (1)-(6) below:

(1) The invention provides a method for determining the load capacitance of a crystal oscillator circuit in which, when a drive current and a load capacitance of the crystal oscillator circuit with a negative resistance RL1 are Ios1 and CL1, respectively, a load capacitance for changing the drive current of the crystal oscillator circuit with a negative resistance RL1 to Ios2 (<Ios1) is set to a value within 10% of a load capacitance CL2 given by CL2=CL1*(Ios2/Ios1)^{1/2}.

(2) The invention provides a method for determining the load capacitance of a crystal oscillator circuit in which, when a negative resistance and a load capacitance of the crystal oscillator circuit with a drive current Ios1 are RL1 and CL1, respectively, a load capacitance for changing the negative resistance of the crystal oscillator circuit with a drive current Ios1 to RL2 is set to a value within 10% of a load capacitance CL2 given by CL2=CL1*(RL1/RL2)^{1/2}.

(3) The invention provides a method for determining the load capacitance of a crystal oscillator circuit in which, wherein a load capacitance CLn (n≧2) is determined with respect to a load capacitance CL1 so that (CLₙ₊₁/CLₙ)²=α holds, where n is an integer greater than or equal to 1 and α is a safety coefficient (2^{-1/2}).

(4) The invention provides a method for determining the load capacitance of a crystal oscillator circuit in which, as a specific load capacitance, CL1=4.4 pF, CL2=3.7 pF, CL3=3.1 pF, CL4=2.6 pF and CL5=2.2 pF are set.

(5) The invention provides a method for determining the negative resistance RL of a crystal oscillator circuit in which, a leakage resistance Rz is assumed to be connected in parallel with a minimum feedback resistance Rfmin between the input side and output side of a CMOS inverter of the crystal oscillator circuit, and a minimum combined feedback resistance RFmin is determined using an equation RFmin=(Rfmin*Rz)/(Rz+Rfmin), and a maximum negative resistance RLmax is determined using an equation (RLmax/RFmin)^{1/2}<α, where α is a safety coefficient (2^{-1/2}). Furthermore, the invention provides a method for determining the negative resistance RL of a crystal oscillator circuit in which, the leakage resistance Rz is assumed to be 4-6 MΩ, preferably 5 MΩ

According to the invention, the load capacitance CL2 of the crystal oscillator circuit is determined based on the ratio of drive currents Ios2/Ios1 of the crystal oscillator circuit, using an equation CL2=CL1*(Ios2/Ios1)^{1/2}, which facilitates designing the crystal oscillator circuit and designing an IC including the crystal oscillator circuit. Or according to the invention, the load capacitance CL2 of the crystal oscillator circuit is determined based on the ratio of negative resistances RL1/RL2 of the crystal oscillator circuit, using an equation CL2=CL1*(RL1/RL2)^{1/2}, which facilitates designing the crystal oscillator circuit and designing an IC including the crystal oscillator circuit. Furthermore, the invention allows a designer to select a load capacitance from predetermined values rather than newly setting a load capacitance, which facilitates designing. Also, since the upper and lower limits of the negative resistance RL are defined, a designer does not have to worry about whether the crystal oscillator circuit will operate properly or not, which facilitates setting the negative resistance. For example, with a minimum feedback resistance Rfmin of 5 MΩ, the negative resistance RL may be set in a range of 300 kΩ<|RL|<1.25 MΩ.

### BRIEF DESCRIPTION OF THE DRAWINGS

FIG. 1 is a graph of the load capacitance CL and drive current Ios of a crystal oscillator circuit;

FIG. 2 illustrates a combined feedback resistance of the crystal oscillator circuit;

FIG. 3 shows an oscillator circuit including a crystal resonator;

FIG. 4 shows an equivalent circuit of the circuit in FIG. 3 between the input/output terminals XCIN and XCOUT on the crystal resonator side;

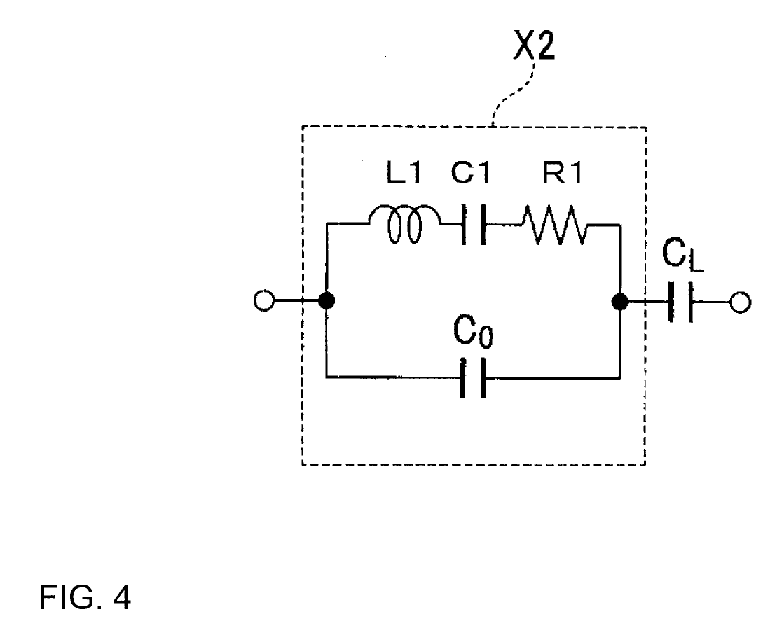

FIG. 5 shows capacitances included in the load capacitance CL;

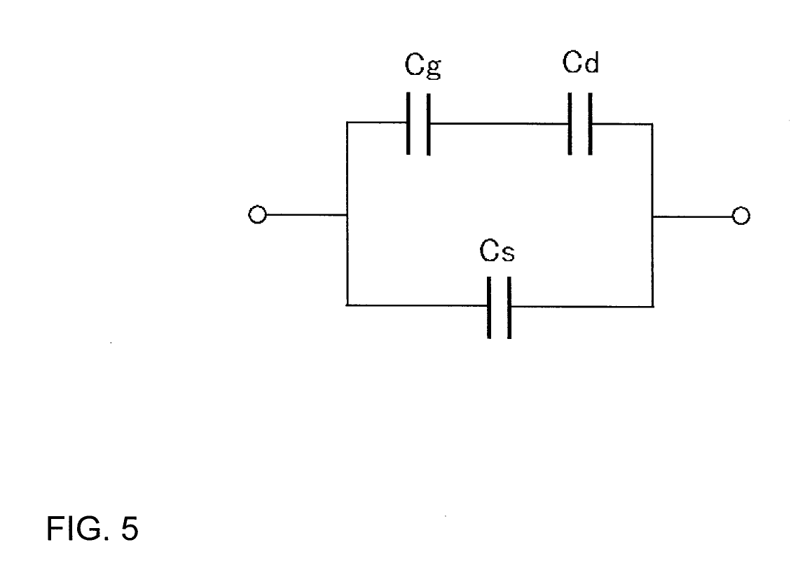

FIG. 6 shows a relation between the drive current and load capacitance CL of the crystal oscillator circuit;

FIG. 7 is a graph showing a relation between the load capacitance and the negative resistance; and

FIG. 8 shows a minimum feedback resistance RFmin and a maximum negative resistance RLmax for various Rfmin.

### DETAILED DESCRIPTION OF THE PREFERRED EMBODIMENTS

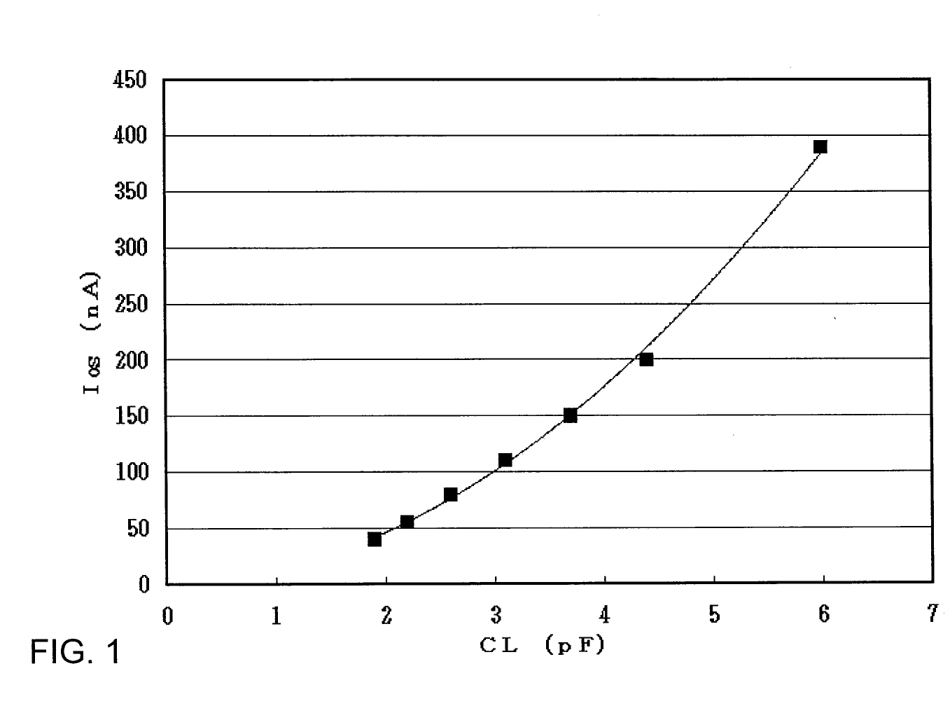

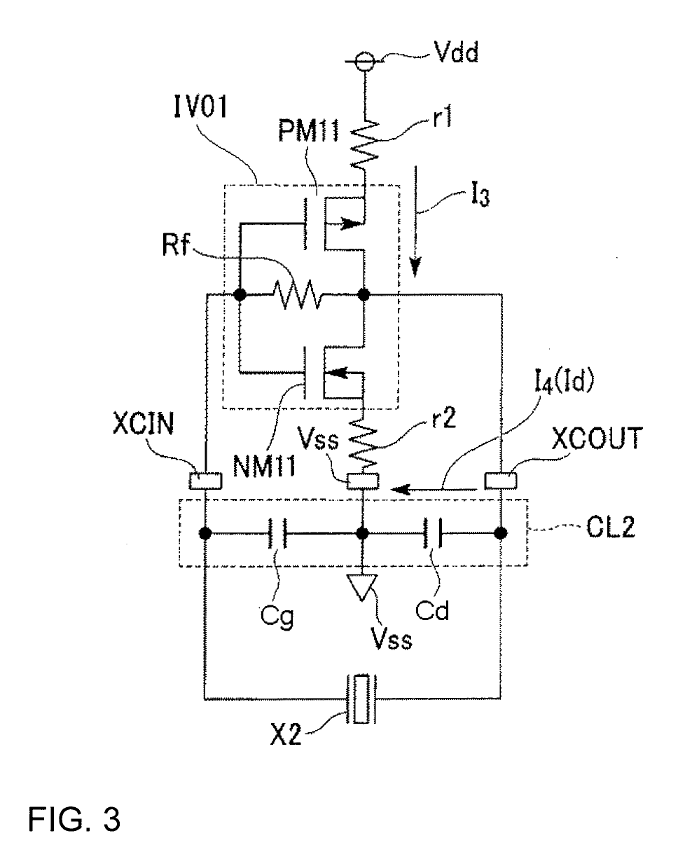

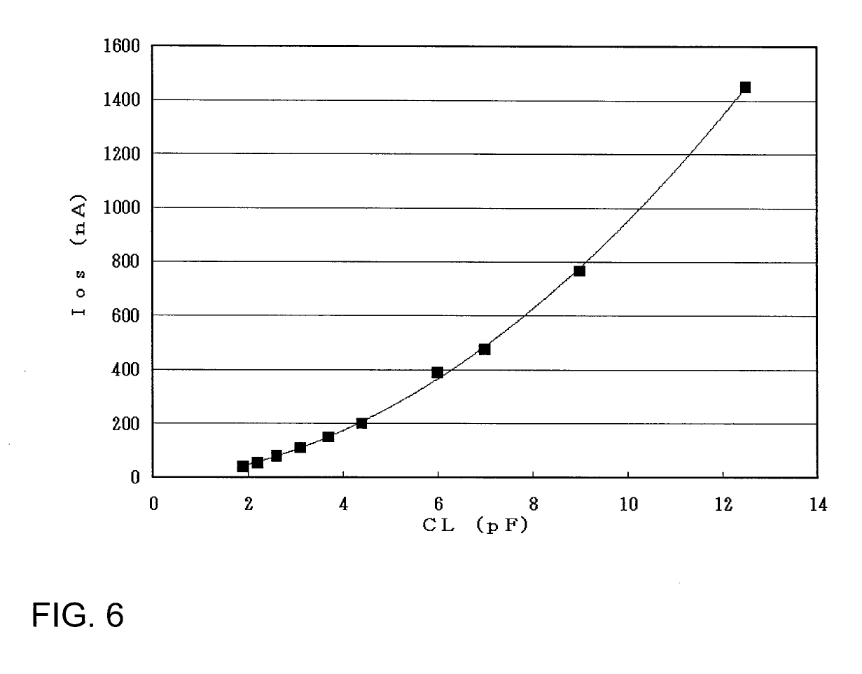

FIG. 1 shows a graph of the measured drive current Ios of a crystal oscillator circuit versus various load capacitances with a negative resistance RL of 1 MΩ) (a 32.768 kHz crystal resonator was used. A circuit shown in FIG. 3 was used. Note that FIG. 1 is the same as a portion of FIG. 6 in which the CL is less than or equal to 6 pF). As seen, reducing the CL causes the drive current Ios to be reduced, allowing reducing consumption current of the crystal oscillator circuit. If it is possible to control the drive current using several load capacitances configured with respect to various negative resistances, a designer of an electronic apparatus including a crystal oscillator circuit (e.g., a microcomputer) can easily design a circuit. Thus, we propose a half-value current option as follows.

The drive current Ios of an IC is given by Ios=Gm*(V−Vth). Assuming Cg=Cd=2CL in Eq. (1), the following holds:

|RL|=|Gm|/(2ωCL)² Eq. (3).

Accordingly, the drive current Ios of the IC is expected to be proportional to (CL)², although some assumptions are made, including an ideal condition of the feedback resistance Rf=∞ in addition to the above. Indeed, applying the approximate equation to the graph in FIG. 1 yields Ios=11.96*(CL)^{1.94} with a correlation coefficient of 0.9999. Also considering measurement error, this prediction is nearly correct. Thus, the following holds:

Ios=a*(CL)² Eq. (4),

where a is a constant that varies depending on the set value of the RL.

Then, since a drive current Ios1 of the crystal oscillator circuit with a negative resistance of RL1 and a load capacitance of CL1 is given by Ios1=a*(CL1)², a load capacitance CL2 of the crystal oscillator circuit with a negative resistance of RL1 and a drive current of Ios2 is estimated as follows:

CL2=CL1*(Ios2/Ios1)^{1/2} Eq. (5).

Practically, since measurement error also exists, setting the load capacitance to a value within about 10% of the value calculated by Eq. (5) allows a drive current of the targeted crystal oscillator circuit to be obtained. For example, with the graph shown in FIG. 1, when the CL1=4.4 pF, Ios1=200 nA. So, in order to halve the Ios to Ios2=100 nA, the CL2 is set to 3.1 pF because of (Ios2/Ios1)^{1/2}=(½)^{1/2}=0.707. Since an actual measured Ios2 was 110 nA, this estimation method works pretty well.

Eq. (5) requires many load capacitances to be prepared in each case. So, an optimum method for setting the load capacitance is described below. Assuming that the first target drive current Ios1 is obtained with a load capacitance of CL1, the second target drive current Ios2 is set to Ios1*(½)^{1/2} (since reduction of the drive current is aimed, Ios2<Ios1). Then the third target drive current Ios3 is set to Ios2*(½)^{1/2}, which corresponds to a half of the first drive current Ios1. As seen, these are a very beautiful relationship correlated by (½)^{1/2}. For example, since the first target drive current Ios1=200 nA is obtained with the CL1=4.4 pF, the second target drive current Ios2 (=Ios1*(½)^{1/2}=142 nA) is obtained with the CL2=CL1*{(½)^{1/2}}^{1/2}=4.4 pF×0.841=3.7 pF. Since the actual measured value is Ios2=150 nA, a nearly correct approximation is given. Next, as described above, the Ios3=100 nA is obtained with the CL3=3.1 pF (the actual measured value is 110 nA). The fourth target value Ios4=Ios3*(½)^{1/2}=71 nA is obtained with the CL4=CL3*{(½)^{1/2}}^{1/2}=3.1 pF×0.841=2.6 pF. Since the actual measured value is Ios4=80 nA, a nearly correct approximation is given. The fifth target value Ios5=Ios4*(½)^{1/2}=50 nA is obtained with the CL5=CL4*{(½)^{1/2}}^{1/2}=2.6 pF×0.841=2.2 pF. Since the actual measured value is Ios4=55 nA, a nearly correct approximation is given. The drive current Ios5 corresponds to ¼ of the first drive current Ios1, and the load capacitance CL5 corresponds to a half (½) of the CL1. The sixth load capacitance CL6 is obtained by CL6=CL5*{(½)^{1/2}}^{1/2}=2.2 pF×0.841=1.9 pF. The seventh load capacitance CL7 is obtained by CL7=CL6*{(½)^{1/2}}^{1/2}=1.9 pF×0.841=1.6 pF. Since the CL is given by CL=Cs+{Cg*Cd/(Cg+Cd)} from Eq. (2), the limit of the CL value cannot be less than or equal to the stray capacitance Cs. Accordingly, the limit value of the CL is considered to be 1.0-1.5 pF, the CL should be set to that extent using the above equation.

As described above, the target drive current Ios can be nearly obtained by using a half value (½) or (½)½ value to preset several load capacitances. In a generalized manner, after setting the CL1 for obtaining the first drive current Ios1, n CLs (CL1-CLn) are prepared to further reduce the drive current. This method determines the load capacitance CLm (m≧2) with respect to the CL1 so that (CLₘ/CLₘ₋₁)²=α holds, where m is an integer greater than or equal to 2 and less than or equal to n, and α=2^{-1/2} (when α is set to this value, the negative resistance RL can be maintained nearly constant and the crystal oscillator circuit achieves stable oscillation. So, α may be called safety coefficient). This allows the drive current Iosₘ to be obtained so that Iosₘ/Iosₘ₋₁=α holds, where m is an integer greater than or equal to 2 and less than or equal to n, and α is a safety coefficient (2^{-1/2}).

This relation holds for one negative resistance RL (1 MΩ) for the graph shown in FIG. 1) and may also hold for another negative resistance RL. When the oscillation margin M is not sufficient, a different negative resistance may be used. In this case, new related group of CLs may be determined from the above equation or the above series of the load capacitances CL (4.4 pF, 3.7 pF, 3.1 pF, 2.6 pF, 2.2 pF, 1.9 pF, . . . ) may be used. Once the first drive current Ios1 is known, the subsequent drive currents can be known using the above-described method. In an opposite manner, with respect to a drive current, a load capacitance to be used may also be selected from the above series of the load capacitances CL (4.4 pF, 3.7 pF, 3.1 pF, 2.6 pF, 2.2 pF, 1.9 pF, . . . ) (however, in this case, a precisely matched drive current may not be selected for a different negative resistance RL, in which a nearly matched drive current may be selected). This means that, for various negative resistance RL, the load capacitances that achieve Iosₘ/Iosₘ₋₁=α (m is an integer greater than or equal to 2, α=2^{-1/2}) with the first drive current Ios1 (CL1=4.4 pF) are 3.7 pF, 3.1 pF, 2.6 pF, 2.2 pF, 1.9 pF, . . . . As described above, only with several set values of the load capacitance prepared, the drive current Ios can be reduced to a desired extent with respect to various negative resistances RL.

According to Eq. (3), the negative resistance RL is inversely proportional to (CL)² with a constant drive current Ios. Accordingly, what is described above may also apply to the negative resistance RL. Thus, the following holds:

|RL|=b*(CL)⁻² Eq. (6),

where b is a constant that varies depending on the set value of the drive current Ios.

When a negative resistance RL1 is given for a load capacitance CL1 of the crystal oscillator circuit with a drive current Ios1, a load capacitance CL2 with a negative resistance RL2 can be estimated as follows:

CL2=CL1*(RL1/RL2)^{1/2} Eq. (7).

Practically, since measurement error also exists, setting the load capacitance CL to a value within about 10% of the value calculated by Eq. (7) allows a negative resistance RL of the targeted crystal oscillator circuit to be obtained.

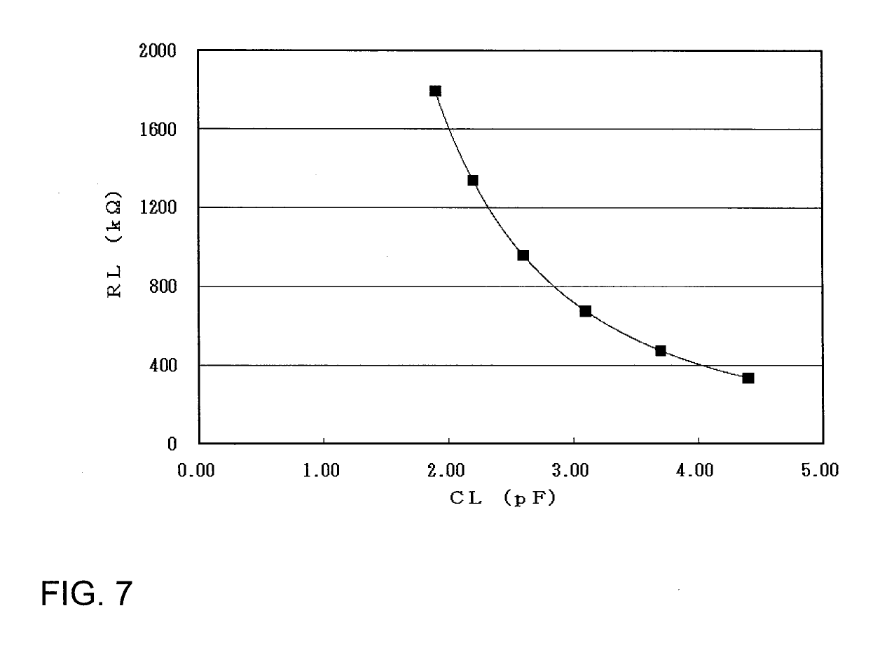

FIG. 7 is a graph showing a relation between the load capacitance CL and the negative resistance RL with the drive current Ios fixed to 75 nA. The negative resistance RL was measured when the load capacitance CL was the above-described set values (4.4 pF, 3.7 pF, 3.1 pF, 2.6 pF, 2.2 pF and 1.9 pF). The approximate equation of the graph is RL=6480×(CL)⁻² (correlation coefficient R=1), indicating that the prediction of Eqs. (6) and (7) is correct.

As for the negative resistance, similarly to the drive current, the target negative resistance RL can be nearly obtained by using a half value (½) or (½)^{1/2} value to preset several load capacitances. In a generalized manner, after setting the CL1 for obtaining the first negative resistance RL1, n CLs (CL1-CLn) are prepared to further increase the negative resistance (in the direction of increasing the oscillation margin M). This method determines the load capacitance CLm (m≧2) with respect to the CL1 so that (CLₘ/CLₘ₋₁)²=α holds, where m is an integer greater than or equal to 2 and less than or equal to n, and α=2^{-1/2} (when α is set to this value, the drive current Ios can be maintained nearly constant). This allows the negative resistance RLₘ to be obtained so that RLₘ/Iosₘ₋₁=1/α holds, where m is an integer greater than or equal to 2 and less than or equal to n, and α is a safety coefficient (2^{-1/2}).

This relation also holds for various drive currents Ios, as is the case for the drive current. Thus, as is the case for the drive current, only with a series of load capacitances CL (4.4 pF, 3.7 pF, 3.1 pF, 2.6 pF, 2.2 pF, 1.9 pF, . . . ) prepared, once the first negative resistance RL1 is known, the subsequent negative resistances RL can be set by selecting an appropriate CL using the above-described method. In an opposite manner, with respect to a negative resistance RL, a load capacitance CL to be used may also be selected from the above series of the load capacitances CL (4.4 pF, 3.7 pF, 3.1 pF, 2.6 pF, 2.2 pF, 1.9 pF, . . . ) (however, in this case, a precisely matched negative resistance RL may not be selected for a different drive current Ios, in which a nearly matched negative resistance RL may be selected). This means that, for various drive current Ios, the load capacitances that achieve RLₘ/RLₘ₋₁=1/α (m is an integer greater than or equal to 2, α=2^{-1/2}) with the first negative resistance RL1 (CL1=4.4 pF) are 3.7 pF, 3.1 pF, 2.6 pF, 2.2 pF, 1.9 pF, . . . . As described above, only with several set values of the load capacitance prepared, the negative resistance RL can be increased to a desired extent with respect to various drive current Ios.

Next, a method for determining the range of the negative resistance RL is described. Previously knowing the range of the negative resistance facilitates designing the oscillator circuit. According to Eq. (1), M=|RL|/R1max, M≧5, then a minimum value of |RL| (denoted by |RLmin| instead of |RL|min for convenience) is given by |RLmin|=5×R1max, where R1max is a maximum value of an equivalent serial resistance of the crystal resonator, which varies depending on the type of the crystal resonator. With an R1max of about 60 kΩ, |RL min|=300 kΩ. That is, |RL|>300 kΩ. With Cg=Cd=2CL, Eq. (1) gives the oscillation margin M as follows:

M={|Gm|/(2ωCL)²}*(1/R1max)=|RL|/R1max Eq. (8).

When the negative resistance RL or the impedance 1/(2ωCL)(Ω) increases, the effect of the Rf (feedback resistance) becomes nonnegligible. Thus, the maximum value RLmax of the negative resistance RL is determined so that the effect of the Rf (feedback resistance) is minimized and the relation equation (8) holds.

The relation between the angular frequency ω₀ and time constant τ₀ of the resonator and the angular frequency ω and time constant τ of the oscillator system is given by: ω=1/τ={Gm/(RF*Cg*Cd)}^{1/2}=ω₀*(RL/RF)^{1/2}, where RF is a feedback resistance (combined feedback resistance described later). Accordingly, ω/ω₀=τ₀/τ=(RL/RF)^{1/2}<1. Then, in order to ensure further stable oscillation, the safety coefficient α=(½)^{1/2} is introduced as follows:

ω/ω₀=τ₀/τ=(RL/RF)^{1/2}<α=(½)^{1/2}=0.707<1 Eq. (9).

The relation of the maximum negative resistance (RL)max and the minimum feedback resistance RFmin is also given by (RL)max/RFmin<α. Accordingly,

RL≦(RL)max<α²×RFmin=0.5×RFmin Eq. (10).

The feedback resistance RF shown in Eqs. (9) and (10) does not always match with the feedback resistance Rf actually applied to the system. Specifically, the feedback resistance RF is a combined value of feedback resistances which actually appears in the crystal oscillator circuit, and may be called a combined feedback resistance. RFmin is the minimum value of the combined feedback resistance and may be called a minimum combined feedback resistance.

For example, the combined feedback resistance RF can be determined as follows.

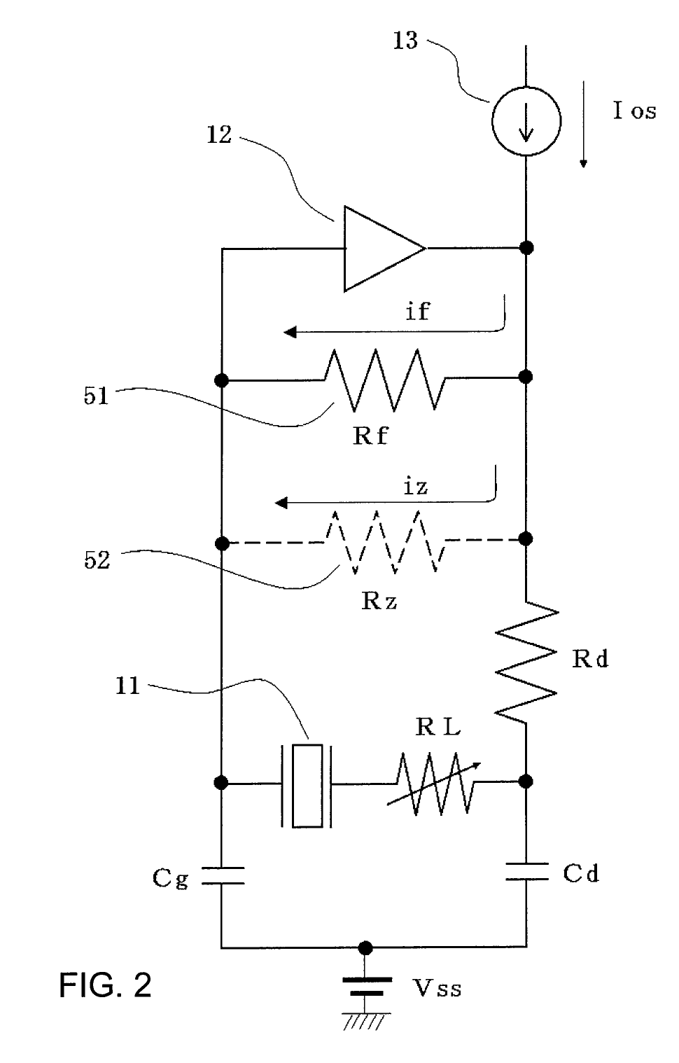

FIG. 2 illustrates a combined feedback resistance of the crystal oscillator circuit. A resistor 51 is a feedback resistor Rf incorporated as a circuit component. However, in actual operation, a current exists that does not flow in the resistor 51 (e.g., a leakage current), so the measured feedback resistance (resistance RF) does not match with the resistor Rf. In other words, a resistance 52 of a current path other than the feedback resistor needs to be considered. The resistance 52 is referred to as a leakage resistance (resistance Rz). This leakage resistance Rz may be considered to be a resistor connected in parallel with the feedback resistor Rf. Where the leakage resistance Rz occurs is unclear, so the leakage resistance Rz may be considered as a virtual resistance. Both of the resistances are combined into a combined feedback resistance (resistance RF) given by:

RF=(Rf*Rz)/(Rf+Rz) Eq. (11)

Since the leakage resistance Rz may be due to a contamination, circuit-related problem or the like, the leakage resistance Rz is not always constant. However, an Rz estimated to be 4-6 MΩ, preferably 5 MΩ or so, may be applied to most crystal oscillator circuits. Also for the minimum combined feedback resistance RFmin and the minimum feedback resistance Rfmin, the following holds:

RFmin=(Rfmin*Rz)/(Rfmin+Rz) Eq. (12).

Since RFmin<Rfmin, it is proved that using the minimum combined feedback resistance RFmin is more practical than using the minimum feedback resistance Rfmin.

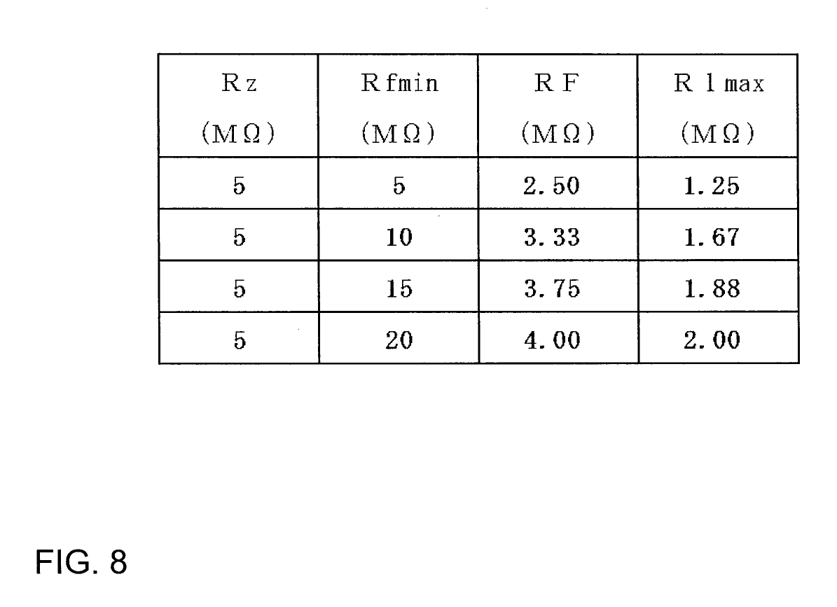

FIG. 8 shows the minimum combined feedback resistance RFmin and maximum negative resistance RLmax calculated with respect to various Rfmin using Eqs. (10) and (12). From these values, the range of the negative resistance RL can be determined as follows:

300 kΩ<|RL|<1.25 MΩ (Rfmin=5 MΩ),

300 kΩ<|RL|<1.67 MΩ (Rfmin=10 MΩ),

300 kΩ<|RL|<1.88 MΩ (Rfmin=15 MΩ), and

300 kΩ<|RL|<2.00 MΩ (Rfmin=20 MΩ).

The relation equation between the negative resistance RL and load capacitance CL of an oscillator circuit having a transconductance Gm is given by:

Gm=a*(CL)²*(RL) Eq. (13)

However, since Eq. (7) holds with a combination of various negative resistances RLp and load capacitances CLp, Eq. (13) is written as follows:

Gm=a*(CLp)²*(RLp) Eq. (14),

where p=1, 2, 3, 4, . . . .

This means that a plurality of combinations of the negative resistance RLp and the load capacitance CLp may provide the same Gm.

According to Eq. (14), the following holds:

Gm=a*(CLₚ)²*(RLₚ)=a*(CLₚ₋₁)²*(RLₚ₋₁).

Then,

(RLₚ)=(RLₚ₋₁)*{(CLₚ₋₁)²/(CLₚ)²} Eq. (15)

Using Eq. (15), the minimum value of the negative resistance can be determined.

For example, assuming that a load capacitance CL with the minimum negative resistance RLmin is (CL)max, and a load capacitance CL with the maximum negative resistance RLmax is (CL)min, the following holds:

RLmin=RLmax*{(CLmin)²/(CLmax)²} Eq. (16).

Thus, the minimum negative resistance can be determined using Eq. (16).

As described above, according to the invention, by presetting several load capacitances CLn (n≧2) with respect to a load capacitance CL1 so that (CLₙ₊₁/CLₙ)²=α holds, where n is an integer greater than or equal to 1 and α is a safety coefficient (2^{-1/2}), and considering a leakage resistance Rz to predetermine the range of the negative resistance, a load capacitance set within the range of the negative resistance determined is selected. This allows a designer to design a predetermined drive current, facilitating designing the crystal oscillator circuit. In the foregoing, the oscillator circuit including the crystal resonator has been generally described. However, the method of the invention for determining the load capacitance and negative resistance of a crystal oscillator circuit is also applicable to a case of using another piezoelectric resonator (e.g., a ceramic resonator) rather than a crystal resonator. The above-described method of the invention can be used in designing an oscillator circuit used for an oscillator or electronic apparatus including a crystal resonator or another piezoelectric resonator. For example, the method may be used for a battery-driven electronic apparatus, such as a watch, mobile phone, personal digital assistant, notebook computer and the like. Furthermore, the method is applicable to a wide range of electronic apparatuses required for energy saving or power saving, such as in-car electronic apparatuses and home-use products including a television-set, refrigerator and air-conditioner.

What is claimed is:

1. A method for determining the load capacitance CL of an oscillator circuit,
wherein, when a drive current and a load capacitance of the oscillator circuit with a negative resistance RL1 are Ios1 and CL1, respectively, a load capacitance CL2 for changing the drive current of the oscillator circuit to Ios2 (<Ios1) is given by:
CL2=CL1*(Ios2/Ios1)^{1/2}.

2. A method for determining the load capacitance CL of an oscillator circuit,
wherein, when a negative resistance and a load capacitance of the oscillator circuit with a drive current Ios1 are RL1 and CL1, respectively, a load capacitance CL2 for changing the negative resistance of the oscillator circuit to RL2 is given by:
CL2=CL1*(RL1/RL2)^{1/2}.

3. A method for determining the load capacitance CL of an oscillator circuit,
wherein a load capacitance CLn (n≧2) is determined with respect to a load capacitance CL1 so that (CLn+1/CLn)²=α holds, where n is an integer greater than or equal to 1 and α is a safety coefficient (2^{-1/2}).

4. An oscillator circuit, wherein the load capacitance CL of the oscillator circuit is designed using the method for determining the load capacitance CL of an oscillator circuit according to claim 1.

5. An electronic apparatus comprising the oscillator circuit according to claim 4.
